(19) United States
(12) Patent Application Publication
(10) Pub. No.: US 2021/0156924 A1
(43) Pub. Date: May 27, 2021

(54) BATTERY UNIT AND METHOD FOR OPERATING A BATTERY UNIT

(71) Applicant: Robert Bosch GmbH, Stuttgart (DE)

(72) Inventors: Andreas Lemke, Berlin (DE); Bjoern Keppler, Waldbronn (DE); Christian Wilhelm, Offenbach An Der Queich (DE); Jens Koerner, Bretzfeld-Scheppach (DE); Klaus-Juergen Schuler, Leingarten (DE); Manuel Fuchs, Heilbronn (DE); Manuel Hohenauer, Beilstein (DE); Ronny Groschke, Mutterstadt (DE)

(21) Appl. No.: 17/054,145

(22) PCT Filed: Apr. 30, 2019
(86) PCT No.: PCT/EP2019/061069

§ 371 Date: Nov. 9, 2020

(30) Foreign Application Priority Data
May 8, 2018 (DE) 10 2018 207 124.1
Apr. 26, 2019 (DE) 10 2019 201 759.2

(51) Int. Cl. G01R 31/3842; H02J 7/00; H01M 10/48; H01M 50/569; H01M 10/42; H01M 10/0525; G01R 31/00; B60R 16/033

(52) U.S. Cl. CPC G01R 31/3842; H02J 7/0048; H01M 10/482; H01M 50/569; H01M 10/425; H01M 2010/4271; G01R 31/006; B60R 16/033; H02J 7/005; H02J 2207/20; H01M 2220/20; H01M 10/0525

(57) ABSTRACT

The invention relates to a battery unit (10) for use in a vehicle electrical system (50) of a motor vehicle, comprising a battery module (20) for producing a first voltage between a positive pole (12) and a negative pole (11), a battery sensor (52), which is electrically connected to the negative pole (11), and a control element (30), which has a first terminal (31) electrically connected to the positive pole (12) and which comprises a DC-to-DC converter (35). The DC-to-DC converter (35) generates a second voltage between a second terminal (32) of the control element (30) and the negative pole (11) in dependence on at least one state variable of the battery module (20), and the battery sensor (52) is electrically connected to the second terminal (32), the battery sensor (52) having means for measuring the second voltage and means for measuring a current flowing through the negative pole (11), or the battery sensor (52) comprising a current sensor and being connected to a control unit which has means for measuring the second voltage and/or means for determining a current flowing through the negative pole (11). The invention also relates to a method for operating a battery unit (10) according to the invention in a vehicle electrical system (50) of a motor vehicle, wherein the second voltage is generated by the DC-to-DC converter (35) of the control element (30) in dependence on the state variable of the battery module (20).

### BACKGROUND OF THE INVENTION

The invention relates to a battery unit for use in a vehicle electric system of a motor vehicle, comprising a battery module for generating a first voltage that is present between a positive pole of the battery unit and a negative pole of the battery unit, a battery sensor that is electrically connected to the negative pole, and a control element that comprises a first terminal with which the positive pole is electrically connected, and which comprises a DC-to-DC converter. The invention also relates to a method for the operation of a battery unit according to the invention in a vehicle electrical system of a motor vehicle.

In conventional motor vehicles with a combustion engine, lead-acid batteries are usually employed as an energy store in a 12 V vehicle electrical system. Such a lead-acid battery, which comprises a positive pole and a negative pole, serves inter alia as a starter battery for starting the combustion engine. The vehicle electrical system and its functions are matched to the properties of the lead-acid battery, for example its internal resistance, charge/discharge curve and its no-load voltage. Vehicle electrical systems of motor vehicles with other rated voltages, 24 V for example, are also known.

A correct detection of the state of the lead-acid battery in the motor vehicle is important here. The state, in particular the state of charge, of the lead-acid battery is used by the motor vehicle as a basis for functions of an energy management system, and can therefore have a massive negative influence on the vehicle behavior and its availability if the detection is incorrect. Safety-relevant functions of the motor vehicle can also be affected.

A battery sensor that is connected to the negative pole and to the positive pole of the lead-acid battery typically performs the detection of the state of the lead-acid battery. The battery sensor here measures, inter alia, a current flowing through the lead-acid battery as well as a voltage present at the poles of the lead-acid battery. The battery sensor ascertains in particular the state of charge and the ageing of the lead acid battery from the measured values.

In the event of failure of a lead-acid battery, it can be advantageous to replace this with a lithium-ion battery. As a result of the different technology, however, a lithium-ion battery has different properties from a lead-acid battery. This includes, inter alia, a lower internal resistance and, in particular, a different relationship between the state of charge and the output voltage. A state of charge ascertained by a battery sensor present in the motor vehicle would, for example, thus be incorrect.

This means that when an exchange is carried out, not only must the conventional lead-acid battery be replaced by a lithium-ion battery, but the battery sensor and its functions must also be replaced. As a result of the high number of variants of motor vehicles available on the market, as well as of lead-acid batteries and battery sensors, this does not appear to be practicable. It is desirable, in particular when a lead-acid battery in a motor vehicle fails, to replace this with a battery unit that comprises a battery module with lithium-ion battery cells. The battery sensor already present in the motor vehicle should here also continue in use.

A generic battery unit with a lithium-ion battery module is known from US 2015/0037616 A1, comprising a housing whose dimensions correspond to those of a housing of a conventional lead-acid battery. The battery unit here also comprises one or a plurality of DC-to-DC converters, whereby a plurality of different output voltages are available at different poles of the battery unit.

A battery is known from US 2015/0293180 A1 that comprises a lithium-ion battery module and a lead-acid battery module. The battery also comprises a battery sensor that ascertains the state of the lithium-ion battery module and of the lead-acid battery module.

A motor vehicle with a lead-acid battery is disclosed in DE 11 2011 104 650 T5. DE 102 48 679 A1 discloses a motor vehicle electrical system with a battery and a DC-to-DC converter. A circuit arrangement for an internal combustion engine that comprises an accumulator battery is known from DE 43 41 279 A1. A hybrid automobile is known from JP 2010-036594 A comprising a battery and a DC-to-DC converter. GB 2496398 A discloses a voltage supply for a vehicle with a battery and an inverter.

### SUMMARY OF THE INVENTION

A battery unit for use in a vehicle electrical system of a motor vehicle is proposed. The battery unit comprises a battery module for generating a first voltage that is present between a positive pole of the battery unit and a negative pole of the battery unit, a battery sensor that is electrically connected to the negative pole, and a control element that comprises a first terminal that is electrically connected to the positive pole. The control element comprises a DC-to-DC converter. The battery unit serves in particular to replace a failed lead-acid battery as a starter battery for a combustion engine of the motor vehicle.

Preferably the battery module of the battery unit comprises a plurality of battery cells that are implemented as lithium-ion cells. In comparison with the cells of lead-acid batteries, lithium-ion cells exhibit in particular an extended service life, an improved cycle capability, a higher energy density and also a higher power density. The type of the battery cells is not here limited to lithium-ion cells. Fundamentally, all kinds of secondary cells that exhibit properties improved over lead-acid battery cells are suitable. For example, lithium-sulfur cells, lithium-air cells, supercapacitors (supercaps, SC), lithium capacitors and battery cells with solid electrolytes are suitable.

According to the invention, the DC-to-DC converter, depending on at least one state variable of the battery module, generates a second voltage that is present between a second terminal of the control element and the negative pole. The battery sensor is here electrically connected to the second terminal of the control element.

The battery sensor for example comprises means for measuring the second voltage, in particular a voltage sensor, and means for measuring a current that flows through the negative pole, in particular a current sensor. The battery sensor comprises, for example, a sensor housing in which means for measuring the second voltage and means for measuring the current that flows through the negative pole are arranged. The battery sensor is, for example, connected to the negative pole by means of a terminal post, and mechanically fastened to the negative pole by means of a screwed connection.

The battery sensor can also comprise a current sensor, in particular a shunt sensor. The shunt sensor here can be implemented as a component with a defined ohmic resistance. The battery sensor is connected here to a control device that comprises means for measuring the second voltage and/or means for ascertaining or measuring a current that flows through the negative pole. The control device in particular comprises a voltmeter for measuring a voltage drop across the ohmic resistance of the shunt sensor. This voltage drop is proportional to the current that is flowing. The control device is here arranged separately from the battery sensor. The control device and the battery sensor are in particular not arranged in the same sensor housing.

The battery sensor is thus not directly electrically connected to the positive pole of the battery unit, but the battery sensor is electrically connected by way of the control element, and thus indirectly to the positive pole of the battery unit. In particular, the first voltage that is generated by the battery module is not present at the battery sensor, but the second voltage that is generated by the DC-to-DC converter of the control element is present at the battery sensor.

The DC-to-DC converter in particular does not generate a constant second voltage for the supply of a consuming unit. The second voltage that is present at the battery sensor depends on at least one state variable of the battery module, and thus serves as a measure of the corresponding state variable for the battery sensor. The DC-to-DC converter can, inter alia, be designed as an electronically controllable DC/DC converter, or as an ohmic voltage divider.

The control element also serves as a source for the supply of electrical energy to the battery sensor. The battery sensor here only requires a relatively small electrical power. The control element is implemented as an almost zero-power source, and delivers a relatively low power to the battery sensor in the range of, for example, 0 mW up to 1000 mW, preferably 200 mW.

According to an advantageous embodiment of the invention, the state variable, depending on which the DC-to-DC converter of the control element generates the second voltage, is a state of charge (SOC) of the battery module. A state of health (SOH) of the battery module, a charge capacity of the battery module, or an internal resistance of the battery module can however also be state variables in the sense of the invention, depending on which the DC-to-DC converter of the control element generates the second voltage.

The first voltage at the positive pole of the battery unit depends in particular on the state of charge of the battery module, and is thus for example a measure of the state of charge of the battery module. The second voltage that is generated by the DC-to-DC converter thus depends for example on the first voltage that is generated by the battery module. The dependency of the second voltage on the state of charge of the battery module, or on the first voltage, is as a rule non-linear.

If a conventional lead-acid battery and a battery module with lithium-ion cells have the same state of charge, the first voltage of the lead-acid battery differs from the first voltage of the battery module with lithium-ion cells.

Preferably the DC-to-DC converter generates the second voltage here in such a way that the second voltage at a given state of charge of the battery module corresponds to a voltage between a positive pole and a negative pole of a lead-acid battery with the same state of charge. The second voltage thus corresponds to the voltage that the lead-acid battery with the same state of charge would have at the positive pole of the lead-acid battery.

The dependency of the second voltage on the state variable of the battery module, depending on which the DC-to-DC converter of the control element generates the second voltage, is as a rule non-linear.

According to one advantageous form of embodiment of the invention, an assignment of the state variable, depending on which the DC-to-DC converter of the control element generates the second voltage, to the second voltage has a fixed specification in the control element. A corresponding assignment table, which can also be referred to as a look-up table, is stored, for example, in the control element for this purpose.

According to another advantageous form of embodiment of the invention, the control element comprises a computing unit that calculates an assignment of the state variable, depending on which the DC-to-DC voltage converter of the control element generates the second voltage, to the second voltage. In this case, the computing unit of the control element comprises, for example, a programmable processor or a microcontroller that calculates the second voltage that is to be generated in accordance with a predefinable algorithm.

The control element comprises, for example, a discrete circuit for drive of the DC-to-DC converter. The said circuit can be implemented either as an analog circuit or also as a digital circuit. When assigning the state variable to the second voltage, the control element can also take further variables into consideration, for example a temperature, that is measured by an appropriate transducer.

According to an advantageous development of the invention, the battery sensor comprises at least one communication interface for communicating with the vehicle control device. The communication interface serves in particular for the transmission of measured values to the vehicle control device. The said communication interface can, for example, be implemented as a digital bus interface, or also as an analog interface.

Alternatively, if the battery sensor comprises the current sensor, in particular the shunt sensor, and is connected to a separate control device, the separate control device can also comprise a communication interface for communicating with a vehicle control device.

The battery unit itself does not have a facility for communicating with the vehicle, in particular with the vehicle control device. The communication takes place indirectly by way of the battery sensor for this reason.

According to an advantageous embodiment of the invention, the battery sensor is electrically connected to the second terminal of the control element by way of an additional contact. The additional contact is thus electrically connected to the battery sensor and to the second terminal of the control element. The control element is, for example, arranged in a housing in which the battery module is also arranged. The control element does not therefore require any additional installation space, and is protected from mechanical influences. The additional contact protrudes, for example, out of the housing. The additional contact can also be designed in the form of a concave socket.

As already explained, the control element is designed as an approximately zero-power source, and only supplies a relatively low power to the battery sensor. The additional contact can therefore be designed as a relatively thin pin plug, and have a diameter in the range between 0.5 mm and 2.0 mm. An electrical conductor that connects the additional contact to the battery sensor can have a correspondingly small cross-section.

The control element can also be arranged outside the housing in which the battery module is arranged. The control element is thereby accessible from outside, and can be exchanged relatively easily.

The control element can further be integrated into a battery management system for monitoring and regulating the battery module. The control element is thus not designed as a separate component, but is part of an existing battery management system.

According to a further development of the invention, the control element delivers a supply current to supply electrical energy to the battery sensor. The battery sensor thus does not require a separate supply terminal for energy supply. Since the control element is designed as an approximately zero-power source, and only delivers a relatively small power to the battery sensor, the supply current is also relatively low. The supply current lies in the range between, for example, 0 mA up to 100 mA, preferably 20 mA.

According to an advantageous embodiment of the invention, the said supply current is in particular a constant direct current. The DC-to-DC converter of the control element is here designed as a controllable ohmic resistor through which the supply current flows. As the supply current flows through the controllable ohmic resistor, it generates a voltage drop. By regulating the value of the ohmic resistor, this voltage drop can be adjusted precisely in a relatively short time. Since the voltage drop can be adjusted relatively quickly, an original dynamic behavior of the voltage that is present at the vehicle electrical system can be maintained. The resistor only lowers the value of the voltage. The original dynamic behavior of the voltage is thus inherently obtained. By controlling the value of the ohmic resistor the second voltage can thus be generated in an almost arbitrary manner, provided the second voltage is smaller than the first voltage. The controllable ohmic resistor can also be referred to as a programmable resistor or as a digital potentiometer.

According to another advantageous embodiment of the invention, the DC-to-DC converter comprises a plurality of diodes that can be connected in series, and a plurality of switches that are connected in each case in parallel with one of the diodes. The diodes here are arranged electrically in such a way that a flow of current from the first terminal of the control element to the second terminal of the control element is possible in the forward direction of the diodes. A voltage drop is generated at each of the diodes through which a current flowing through the control element, in particular the supply current for supply of the battery sensor, flows. The said current flows here through one of the diodes when the parallel-connected switch is open. The said current flows through the parallel-connected switch when the switch is closed. By opening or closing the individual switches, the voltage drop generated in the DC-to-DC converter can thus be adjusted precisely, and in a relatively short time. Since the voltage drop can be adjusted relatively quickly, an original dynamic behavior of the voltage that is present at the vehicle electrical system, can be maintained. The diodes only lower the value of the voltage. By opening or closing the individual switches, the second voltage can thus be generated in an almost arbitrary manner, provided the second voltage is smaller than the first voltage.

Preferably the DC-to-DC converter comprises a plurality of switch units, which are designed as MOSFETs, i.e. metal-oxide semiconductor field-effect transistors. The said switch units each comprise a parallel circuit consisting of a switch and one of the diodes. Each of the said diodes here represents in particular a back diode, or body diode, of the respective switch unit.

The DC-to-DC converter preferably also comprises a control unit for driving the switches. The control unit is, for example, designed in the form of a microcontroller.

According to an advantageous development of the invention, the control unit comprises a plurality of bistable flip-flops for controlling the switches. Such a bistable flip-flop represents a 1-bit storage cell. Each of the bistable flip-flops comprises a control output each of which is connected to one control input of a switch, or a switch unit, of the DC-to-DC converter. Preferably the bistable flip-flops are implemented as CMOS RS flip-flops. Such a bistable flip-flop makes it possible to drive a switch, for example a switch unit, of the DC-to-DC converter permanently, but without permanent power consumption.

The DC-to-DC converter can also be designed as a fixed ohmic resistor. The DC-to-DC converter can, for example, also be designed as an electronically controllable DC/DC converter. In this case, the second voltage can be almost freely set, almost independently of the value of the first voltage. In particular, when a DC/DC converter is used, the second voltage can also be larger than the first voltage.

A method for the operation of a battery unit according to the invention in a vehicle electrical system of a motor vehicle is also proposed. The battery unit here is installed in the motor vehicle, and the positive pole of the battery unit is connected to the vehicle electrical system of the motor vehicle. According to the invention, the second voltage is generated here by the DC-to-DC converter of the control element depending on the state variable of the battery module.

According to an advantageous development of the invention, the second voltage is generated here in such a way that the battery sensor outputs a control signal by way of a communication interface for communicating with a vehicle control device, depending on a value of the second voltage. A particular voltage level can be defined for this purpose, and assigned to particular control signals. For example, a voltage level of 1 V can be assigned to a control signal that indicates that the battery module is faulty or is no longer connected to the vehicle electrical system of the motor vehicle. For example, with a rated voltage of 12 V, a voltage level of 20 V can be assigned to a control signal that indicates that the battery module should not at present be charged. With a rated voltage of 24 V, a voltage level of 40 V can, for example, be assigned to a control signal that indicates that the battery module should not at present be charged.

The battery unit, or the control element, or a battery management system present in the battery unit, do not themselves have any way of communicating with the vehicle, in particular with the vehicle control device. The communication takes place indirectly by way of the battery sensor for this reason.

A battery unit according to the invention, and a method according to the invention, are advantageously used in a vehicle electrical system of a motor vehicle, in particular of a motor vehicle with a combustion engine, and in particular to replace a conventional lead-acid battery. Other uses, for example in the vehicle electrical systems of other motor vehicles such as, for example, hybrid vehicles, plug-in hybrid vehicles and electric vehicles are also however conceivable.

### Advantages of the Invention

The invention makes possible a replacement of a conventional 12 V lead-acid battery with a 12 V lithium-ion battery, while ensuring all functionalities, in particular of the energy management, in the motor vehicle. A battery sensor present in the motor vehicle that is matched to the properties of the replaced lead-acid battery can be retained and is thus part of the newly inserted battery unit. The control element with the DC-to-DC converter thus makes the use of a lithium-ion battery possible in motor vehicles that are matched to the properties of a lead-acid battery. The control element can, in particular, be designed as an almost zero-power source, and thus draws only a relatively small amount of energy from the battery module.

Through the appropriate design of the control element, the first voltage that is present at the positive pole can be mapped to a second voltage at the battery sensor that corresponds to the voltage at the pole terminals of the lead-acid battery under the same conditions, in particular with the same state of charge. In this way it is ensured that the battery state detection of the motor vehicle functions correctly, and the functionalities in the motor vehicle are maintained.

### BRIEF DESCRIPTION OF THE DRAWINGS

Forms of embodiment of the invention are explained in more detail with reference to the drawings and the subsequent description, in which:

FIG. 1 shows a schematic illustration of a battery unit according to a first form of embodiment in a vehicle electrical system of a motor vehicle,

FIG. 2 shows a schematic illustration of a battery unit according to a second form of embodiment in a vehicle electrical system of a motor vehicle,

FIG. 3 shows a schematic illustration of a battery unit according to a third form of embodiment in a vehicle electrical system of a motor vehicle,

FIG. 4 shows a perspective illustration of a battery unit according to the first form of embodiment, without battery sensor,

FIG. 5 shows a battery sensor,

FIG. 6 shows a schematic illustration of a control element, and

FIG. 7 shows a schematic illustration of a bistable flip-flop.

### DETAILED DESCRIPTION

In the following description of the forms of embodiment of the invention, elements that are the same or similar are identified by the same reference signs, wherein a repeated description of these elements is omitted in individual cases. The figures only represent the object of the invention schematically.

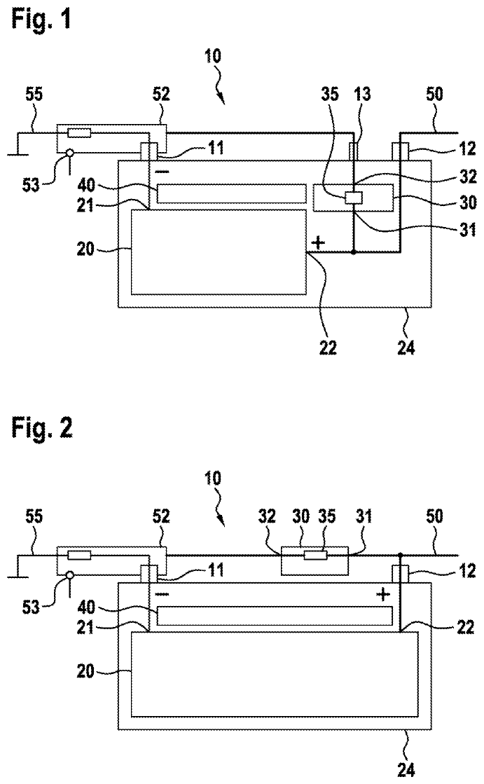

FIG. 1 shows a schematic illustration of a battery unit 10 according to a first form of embodiment, in a vehicle electrical system 50 of a motor vehicle, not illustrated here. In this context the voltage-carrying supply lines in the motor vehicle are referred to as the vehicle electrical system 50. In the present case the vehicle electrical system 50 has a nominal voltage of 12 V with respect to a ground line 55 in the motor vehicle. The battery unit 10 comprises a battery sensor 52.

The battery unit 10 comprises a positive pole 12 that is connected to the vehicle electrical system 50. The battery unit 10 also comprises a negative pole 11 that is connected to the battery sensor 52. The battery sensor 52 is also connected to the ground line 55. The battery sensor 52 is further connected by means of a communication interface 53 to a higher-level vehicle control device.

The battery unit 10 comprises a battery module 20 which comprises a plurality of battery cells that are implemented as lithium-ion cells. The battery cells are, for example, connected in series, and deliver a nominal voltage of 12 V. The battery module 20 comprises a negative terminal 21 and a positive terminal 22. The nominal voltage of 12 V delivered by the said battery cells is present between the terminals 21, 22 of the battery module 20.

The battery module 20 is arranged in a housing 24. The negative pole 11 and the positive pole 12 protrude out of the housing 24. The negative terminal 21 is electrically connected to the negative pole 11, and the positive terminal 22 is electrically connected to the positive pole 12. The nominal voltage of 12 V delivered by the battery cells of the battery module 20 thus also lies between the poles 11, 12.

The battery unit 10 also comprises a battery management system 40 for monitoring and regulating the battery module 20. The battery management system 40 is in the present case also located inside the housing 24.

The battery unit 10 further comprises a control element 30. The control element 30 comprises a first terminal 31 that is electrically connected to the positive pole 12. The control element 30 also comprises a second terminal 32 that is electrically connected to the battery sensor 52. The control element 30 is in the present case also located in the housing 24. The battery sensor 52 is in the present case located outside the housing 24. The electrical connection of the second terminal 32 of the control element 30 to the battery sensor 52 takes place in the present case by way of an additional contact 13 that protrudes out of the housing 24. The additional contact 13 can also be designed in the form of a concave socket.

The nominal voltage of 12 V, which is referred to below as the first voltage, delivered by the battery module 20 is present at the first terminal 31 of the control element 30. A second voltage that is generated by the control element 30 is generated at the second terminal 32 of the control element 30. The second voltage is also present at the additional contact 13 and at the battery sensor 52.

The control element 30 comprises a DC-to-DC converter 35 for this purpose, which generates the second voltage at the second terminal 32 depending on a state variable of the battery module 20. The said state variable of the battery module 20 is, for example, a state of charge (SOC) of the battery module 20. To a first approximation it can be assumed that the state of charge of the battery module 20 depends on the first voltage at the positive pole 12. An assignment of the first voltage to the second voltage has a fixed specification in the control element 30, for example in the form of an assignment table.

The DC-to-DC converter 35 can be a controllable DC/DC converter. The DC-to-DC converter 35 can also be designed as an ohmic voltage divider. Moreover the DC-to-DC converter 35 can be configured as a fixed or as a controllable ohmic resistor. The DC-to-DC converter 35 can also comprise a plurality of diodes D1, D2, D3, D4 connected in series, as is illustrated by way of example in FIG. 6.

The battery sensor 52 measures, inter alia, the second voltage, which usually differs from the first voltage. The battery sensor 52 also measures the current flowing from the ground line 55 to the negative pole 11, which corresponds to a current through the battery module 20 and through the battery unit 10.

The battery sensor 52 ascertains a state of the battery module 20 from the measured second voltage and from the measured current through the battery module 20. The state of the battery module 20 comprises in particular a state of charge of the battery module 20. The battery sensor 52 transmits the ascertained state of the battery module 20 to the higher-level vehicle control device by way of the communication interface 53.

FIG. 2 shows a schematic illustration of a battery unit 10 according to a second form of embodiment in a vehicle electrical system 50 of a motor vehicle. The battery unit 10 according to the second form of embodiment is largely the same as the battery unit 10 of the first form of embodiment illustrated in FIG. 1. Only the differences will be discussed below.

The control element 30 is located in the present case outside the housing 24 in which the battery module 20 is arranged. An additional contact 13 protruding from the housing 24 is not provided in the present case. The second terminal 32 of the control element 30 is in the present case electrically connected directly to the battery sensor 52. The first terminal 31 of the control element 30 is electrically connected to the positive pole 12.

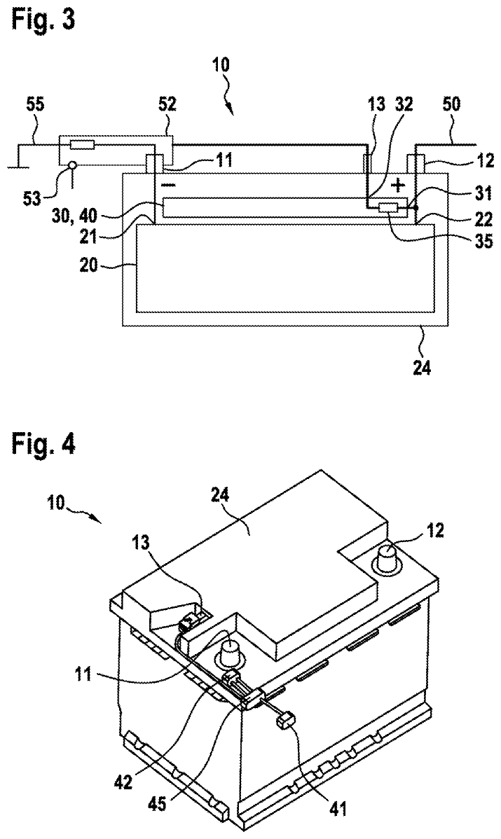

FIG. 3 shows a schematic illustration of a battery unit 10 according to a third form of embodiment in a vehicle electrical system 50 of a motor vehicle. The battery unit 10 according to the third form of embodiment is largely the same as the battery unit 10 of the first form of embodiment illustrated in FIG. 1. Only the differences will be discussed below.

In the present case the control element 30 is integrated into the battery management system 40 for monitoring and regulating the battery module 20. The control element 30 and the battery management system 40 thus form one unit which in the present case is arranged inside the housing 24 in which the battery module 20 is also arranged. The electrical connection of the second terminal 32 of the control element 30 to the battery sensor 52 takes place in the present case, as also in the battery unit 10 according to the first form of embodiment, by way of an additional contact 13 that protrudes out of the housing 24. The additional contact 13 can also be designed in the form of a concave socket.

FIG. 4 shows a perspective illustration of the battery unit 10 according to the first form of embodiment, wherein the battery sensor 52 is not illustrated. The battery unit 10 comprises the housing 24, out of which the negative pole 11, the positive pole 12 and the additional contact 13 protrude. The additional contact 13 can also be designed in the form of a concave socket. The housing 24 is approximately prismatic in design, in particular rectangular, wherein the dimensions of the housing 24 correspond to the dimensions of a conventional lead-acid battery.

The additional contact 13 is electrically connected by means of a cable to an adapter 45. The adapter 45 is electrically connected by means of a cable to a first plug-in connector 41. The first plug-in connector 41 serves to connect to a corresponding mating connector of the vehicle control device, not illustrated here. The first plug-in connector 41 provides the communication interface 53.

The adapter 45 is also electrically connected by means of a cable to a second plug-in connector 42. The second plug-in connector 42 serves to connect to the battery sensor 52, not illustrated here. The second plug-in connector 42 provides the communication interface 53 and the electrical connection to the additional contact 13.

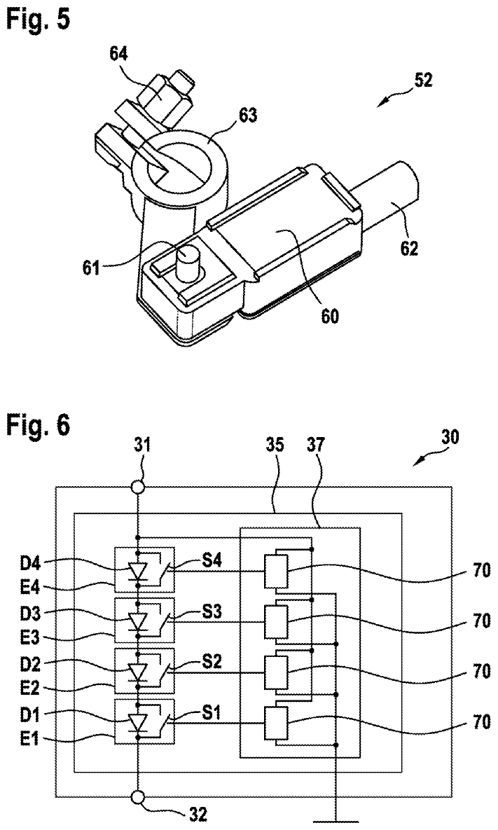

FIG. 5 shows the battery sensor 52 of the battery unit 10 of FIG. 4. The battery sensor 52 comprises a sensor housing 60 in which, inter alia, the means for measuring the second voltage and the means for measuring the current that flows through the negative pole 11 are arranged. In the sensor housing 60, means for communicating with the vehicle control device by way of the communication interface 53 are further arranged.

The battery sensor 52 comprises a terminal bolt 61 that serves for connection to the ground line 55 of the vehicle. The battery sensor 52 comprises a plug 62 that serves for connection of the second plug-in connector 42. The battery sensor 52 comprises a terminal post 63 that serves for connection at the negative pole 11. The terminal post 63 can be mechanically fastened to the negative pole 11 by means of a screwed connection 64.

FIG. 6 shows a schematic illustration of a control element 30 with a DC-to-DC converter 35. In the form of embodiment shown here, the DC-to-DC converter 35 comprises a plurality of switch units E1, E2, E3, E4. The switch units E1, E2, E3, E4 are each designed as a MOSFET, i.e. as a metal oxide semiconductor field effect transistor. The switch units E1, E2, E3, E4 each comprise a parallel circuit consisting of a controllable switch S1, S2, S3, S4 and a diode D1, D2, D3, D4. Each of the said diodes D1, D2, D3, D4 here represents a back diode or body diode of the respective switch unit E1, E2, E3, E4. It is also conceivable that the diodes D1, D2, D3, D4 are designed as switch elements separate from the switches S1, S2, S3, S4.

The diodes D1, D2, D3, D4 of the DC-to-DC converter 35 are connected in series. A switch S1, S2, S3, S4 is connected in parallel with each of the diodes D1, D2, D3, D4. The diodes D1, D2, D3, D4 are arranged electrically in such a way that the flow of current from the first terminal 31 of the control element 30 to the second terminal 32 of the control element 30, is possible in the forward direction of the diodes D1, D2, D3, D4. A voltage drop is generated at each of the diodes D1, D2, D3, D4 through which a current flows, for example a supply current for supply of the battery sensor 52.

By opening and closing the individual switches S1, S2, S3, S4, the second voltage present at the second terminal 32 can be generated almost arbitrarily. The second voltage here is smaller than the first voltage present at the first terminal 31, and can be varied in discrete steps.

When one of the switches S1, S2, S3, S4 is opened, the said current flows through the diode D1, D2, D3, D4 that is connected in parallel with this switch S1, S2, S3, S4, and generates a voltage drop at the said diode D1, D2, D3, D4. When one of the switches S1, S2, S3, S4 is closed, said current flows through this switch S1, S2, S3, S4 and does not generate a voltage drop at the diode D1, D2, D3, D4 that is connected in parallel with this switch S1, S2, S3, S4. By opening or closing the individual switches S1, S2, S3, S4 the voltage drop generated in the DC-to-DC converter 35 can thus be adjusted precisely.

The DC-to-DC converter 35 also comprises a control unit 37. The control unit 37 serves to drive the switches S1, S2, S3, S4. The control unit 37 can, for example, be designed in the form of a microcontroller.

In the present case, the control unit 37 comprises a plurality of bistable flip-flops 70 for drive of the switches S1, S2, S3, S4. Such a bistable flip-flop 70 represents a 1-bit memory cell. The switches S1, S2, S3, S4 of the DC-to-DC converter 35 can be driven permanently by means of the bistable flip-flops 70.

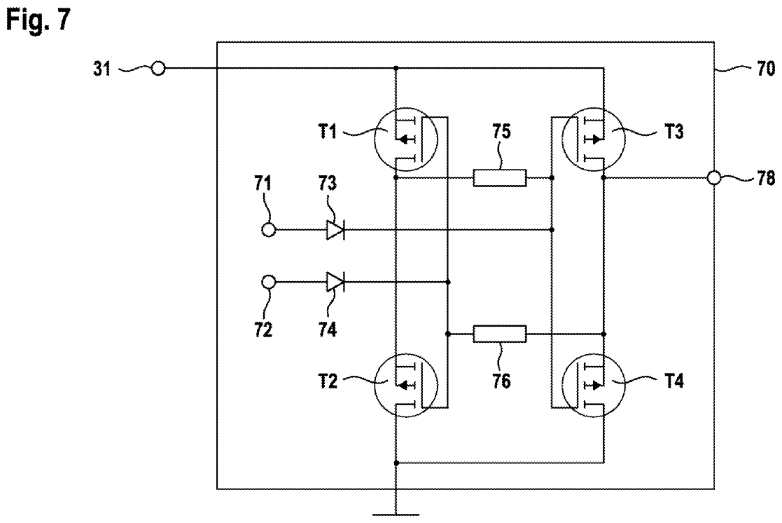

FIG. 7 shows a schematic illustration of a bistable flip-flop 70. The bistable flip-flop 70 comprises a control output 78 that is electrically connected to a control input of one of the switches S1, S2, S3, S4 of the DC-to-DC converter 35. The bistable flip-flop 70 is, for example, implemented as a CMOS RS flip-flop, and therefore has an extremely low power requirement.

The bistable flip-flop 70 is also electrically connected to the first terminal 31 of the control element 30, and thus also to the positive terminal 22 of the battery module 20 as well as to the positive pole 12 of the battery unit 10. The bistable flip-flop 70 is also electrically connected to a ground terminal. The ground terminal can, depending on the arrangement of the control element 30, be the negative terminal 21 of the battery module 20, the negative pole 11 of the battery unit 10, or the ground line 55.

The bistable flip-flop 70 also comprises a reset input 71, a set input 72, a reset input diode 73 and a set input diode 74. The bistable flip-flop 70 further comprises a first memory transistor T1, a second memory transistor T2, a third memory transistor T3, a fourth memory transistor T4, a first coupling resistor 75 and a second coupling resistor 76.

If a voltage pulse of about 12 V is present briefly at the set input 72, the bistable flip-flop 70 is set. The nominal voltage of 12 V is then present at the control output 78. The switch S1, S2, S3, S4 of the DC-to-DC converter 35 that is electrically connected to the bistable flip-flop 70 is thereupon closed. When the said voltage pulse is no longer present, the bistable flip-flop 70 thus remains set, and the nominal voltage of 12 V remains at the control output 78. The switch S1, S2, S3, S4 that is electrically connected to the bistable flip-flop 70 thus remains closed.

If a voltage pulse of about 12 V is briefly present at the reset input 71, the bistable flip-flop 70 is reset. A voltage of about 0 V is then present at the control output 78. The switch S1, S2, S3, S4 of the DC-to-DC converter 35 that is electrically connected to the bistable flip-flop 70 is thereupon opened. When the said voltage pulse is no longer present, the bistable flip-flop 70 remains reset, and the voltage of about 0 V remains at the control output 78. The switch S1, S2, S3, S4 that is electrically connected to the bistable flip-flop 70 thus remains open.

The invention is not restricted to the exemplary embodiments described here and the aspects emphasized therein. Rather, a large number of variations that are within the scope of possible skilled activity is possible within the scope stated by the claims.

1. A battery unit (10) for use in a vehicle electrical system (50) of a motor vehicle, the battery comprising:
a battery module (20) for generating a first voltage that is present between a positive pole (12) and a negative pole (11),
a battery sensor (52) that is electrically connected to the negative pole (11), and
a control element (30) that has a first terminal (31), that is electrically connected to the positive pole (12), and that comprises a DC-to-DC converter (35),
wherein
the DC-to-DC converter (35) generates a second voltage depending on at least one state variable of the battery module (20) that is present between the second terminal (32) of the control element (30) and the negative pole (11), and wherein
the battery sensor (52) is electrically connected to the second terminal (32),
wherein the battery sensor (52) comprises means for measuring the second voltage and means for measuring the current that is flowing through the negative pole (11), or
wherein the battery sensor (52) comprises a current sensor, and is connected to a control device,
which comprises means for measuring the second voltage and/or means for ascertaining a current that is flowing through the negative pole (11).

2. The battery unit (10) as claimed in claim 1, wherein the state variable is a state of charge.

3. The battery unit (10) as claimed in claim 2, wherein the DC-to-DC converter (35) generates the second voltage in such a way that at a given state of charge of the battery module (20) the second voltage corresponds to a voltage between a positive pole (12) and a negative pole (11) of a lead-acid battery with the same state of charge.

4. The battery unit (10) as claimed in claim 1, wherein an assignment of the state variable to the second voltage has a fixed specification in the control element (30).

5. The battery unit (10) as claimed in claim 1, wherein the control element (30) comprises a computing unit that calculates an assignment of the state variable to the second voltage.

6. The battery unit (10) as claimed in claim 1, wherein the battery sensor (52) comprises at least one communication interface (53) for communicating with a vehicle control device.

7. The battery unit (10) as claimed in claim 1, wherein the battery sensor (52) is electrically connected to the second terminal (32) of the control element (30) by way of an additional contact (13).

8. The battery unit (10) as claimed in claim 1, wherein the control element (30) delivers a supply current to supply electrical energy to the battery sensor (52).

9. The battery unit (10) as claimed in claim 8, wherein the supply current is a direct current, and that the DC-to-DC converter (35) is formed as a controllable ohmic resistor through which the supply current flows.

10. The battery unit (10) as claimed in claim 1, wherein the DC-to-DC converter (35) comprises a plurality of diodes (D1, D2, D3, D4) connected in series, and that the DC-to-DC converter (35) comprises a plurality of switches (S1, S2, S3, S4) each of which is connected in parallel with one of the diodes (D1, D2, D3, D4).

11. The battery unit (10) as claimed in claim 1, wherein the DC-to-DC converter (35) comprises a plurality of switch units (E1, E2, E3, E4) that are designed as MOSFETs, and each of which comprises a parallel circuit consisting of a switch (S1, S2, S3, S4) and one of the diodes (D1, D2, D3, D4).

12. The battery unit (10) as claimed in claim 10, herein the DC-to-DC converter (35) comprises a control unit (37) for driving the switches (S1, S2, S3, S4).

13. The battery unit (10) as claimed in claim 12, wherein the control unit (37) comprises a plurality of bistable flip-flops (70) for driving the switches (S1, S2, S3, S4).

14. A method for operating a battery unit (10) as claimed in claim 1 in a vehicle electrical system (50) of a motor vehicle, wherein the second voltage is generated by the DC-to-DC converter (35) of the control element (30) depending on the state variable of the battery module (20).

15. The method as claimed in claim 14, wherein the second voltage is generated in such a way that the battery sensor (52) outputs a control signal by way of a communication interface (53) for communicating with a motor vehicle control device depending on a value of the second voltage.

16. A vehicle electrical system (50) of a motor vehicle, the vehicle electrical system comprising:
a battery module (20) for generating a first voltage that is present between a positive pole (12) and a negative pole (11),
a battery sensor (52) that is electrically connected to the negative pole (11), and
a control element (30) that has a first terminal (31), that is electrically connected to the positive pole (12), and that comprises a DC-to-DC converter (35),
wherein
the DC-to-DC converter (35) generates a second voltage depending on at least one state variable of the battery module (20) that is present between the second terminal (32) of the control element (30) and the negative pole (11), and wherein
the battery sensor (52) is electrically connected to the second terminal (32),
wherein the battery sensor (52) comprises means for measuring the second voltage and means for measuring the current that is flowing through the negative pole (11), or
wherein the battery sensor (52) comprises a current sensor and is connected to a control device, which comprises means for measuring the second voltage and/or means for ascertaining a current that is flowing through the negative pole (11).
